(19) United States
(12) Patent Application Publication
(10) Pub. No.: US 2020/0379048 A1
(43) Pub. Date: Dec. 3, 2020

(54) THREE-ELECTRODE BATTERY CELL SETUP FOR POSITIVE AND NEGATIVE VOLTAGE WINDOW UTILIZATION

(71) Applicant: SF Motors, Inc., Santa Clara, CA (US)

(72) Inventors: Yu-Hsin Huang, Milpitas, CA (US); Chengyu Mao, Santa Clara, CA (US); Chien-Po Huang, Campbell, CA (US); Ying Liu, Santa Clara, CA (US); Yifan Tang, Santa Clara, CA (US)

(73) Assignee: SF Motors, Inc., Santa Clara, CA (US)

(21) Appl. No.: 16/423,944

(22) Filed: May 28, 2019

(51) Int. Cl. G01R 31/367; H01M 10/42; H01M 10/44; G01R 31/3835; G01R 31/396

(52) U.S. Cl. CPC G01R 31/367; H01M 10/4285; G01R 31/396; G01R 31/3835; H01M 10/44

(57) ABSTRACT

A three-electrode battery cell precisely measures the anode and cathode during cell operation. The successful interpretation of 3-E cell measurements enables accurate tuning of N/P ratio, fine control of electrode potential during operations, and precise cell capacity prediction during early-stage design. The cost-intensive full cell assembly and time-consuming cell testing can be eliminated, and 3-electrode cell testing and analysis can be used to achieve reliable materials sourcing and state-of-the-art cell design with high accuracy and efficiency. The three-electrode cell can be used to analyze and test battery cell designs during pre-production to determine and optimize the capacity, N/P ratio, and voltage window information for mass production of a particular battery design.

### BACKGROUND

Many aspects of a battery cell should be considered in the design of a lithium ion battery. To achieve high quality cell design, insight on anode and cathode operation potential (versus Li/Li+) windows is important. Current battery systems do not offer an easy solution to monitoring the working potential for a battery cathode and anode. With these issues, limited knowledge regarding the cell chemistry, which are critical to guide cell design, can be obtained using full cell measurement, although the full cell assembly and testing itself requires significant cost and time.

### SUMMARY

The present technology, roughly described, utilizes a three-electrode battery cell to precisely measure the anode and cathode potentials during cell operation. The successful interpretation of 3-E cell results in this methodology will enable accurate tuning of N/P Ratio, fine control of electrode potential during operations, and precisely cell capacity predication during early-stage design. Building on these features, the cost-intensive full cell assembly and time-consuming cell testing can be eliminated, and one can utilize our newly developed technology based on 3-E cell testing and analysis to achieve reliable materials sourcing and state-of-the-art cell design with high accuracy and efficiency. In some instances, the three-electrode cell is used to analyze and test battery cell designs during pre-production to determine the capacity, N/P ratio, and voltage window information for a particular battery.

In some instances, a system for analyzing a battery cell design using a three-electrode battery cell includes one or more processors, memory, and one or more modules stored in memory. The modules can be executed by the processors to measure an anode potential of a three-electrode battery cell anode during charging and discharging of the three-electrode battery cell. The three-electrode battery cell can the anode, a cathode, and a reference electrode. The reference electrode can be displaced between the anode and the cathode and enable a half cell potential to be measured for the anode and a half cell potential to be measured for the cathode. The executed modules can also measure the cathode potential during charging and discharging, and optimize design of the three-electrode battery cell based on the measured anode potential measurement and cathode potential measurement.

In some instances, a system for analyzing a battery cell design using a three-electrode battery cell includes one or more processors, memory, and one or more modules stored in memory. The modules can be executed by the processors to measure the cathode potential during charge and discharge a cathode of the three-electrode battery cell, the three electrode battery cell including an anode, the cathode, and a reference electrode, the reference electrode displaced between the anode and the cathode and enabling a half cell potential to be measured for the anode and a half cell potential to be measured for the cathode. The executed modules can also measure the cathode potential during discharging; and optimize design of the three-electrode battery cell based on the maximum cathode voltage during the charging and discharging.

### BRIEF DESCRIPTION OF DRAWINGS

FIG. 1 illustrates a blown-up view of a three-electrode battery cell.

FIG. 2 is a block diagram of a system for computing information from measurements of a three-electrode battery cell.

FIG. 3 is a method for manufacturing a three-electrode battery cell.

FIG. 4 is a method for tuning a negative positive ratio.

FIG. 5 illustrates a plot of an operational voltage window for a cell having an N/P ratio less than one.

FIG. 6 illustrates in anode operational potential for cell within N/P ratio larger than one.

FIG. 7 is a method for determining electrolyte stability from a voltage window.

FIG. 8 illustrates a plot of a cathode potential over time.

FIG. 9 illustrates a method for predicting capacity from half-cell potential measurements.

FIG. 10 illustrates an overlap of three voltage profiles for a cathode potential, and a potential, and a cell voltage.

FIG. 11 illustrates a plot of an anode voltage versus time.

FIG. 12 illustrates a plot of a cathode voltage versus time.

FIG. 13 is a block diagram of a computing environment for implementing the present technology.

### DETAILED DESCRIPTION

The present technology, roughly described, utilizes a three-electrode battery cell to precisely measure the anode and cathode during cell operation. The successful interpretation of 3-E cell measurements enables accurate tuning of N/P Ratio, fine control of electrode potential during operations for electrolyte oxidation stability, and precise cell capacity prediction during early-stage design. Building on these features, the cost-intensive full cell assembly and time-consuming cell testing can be eliminated, and 3-electrode cell testing and analysis can be used to achieve reliable materials sourcing and state-of-the-art cell design with high accuracy and efficiency. In some instances, the three-electrode cell is used to analyze and test battery cell designs during pre-production to determine and optimize the capacity, N/P ratio, and voltage window information for mass production of a particular battery design.

The three-electrode battery cell has an anode, cathode, and a third electrode—a reference electrode—displaced between the anode and the cathode. The reference electrode allows for direct measurement of the anode potential and the cathode potential, during both battery cell charging and discharge. From the direct measurements, many calculations can be made on behalf of the battery cell, which in turn can be used to optimize the design of the battery cell.

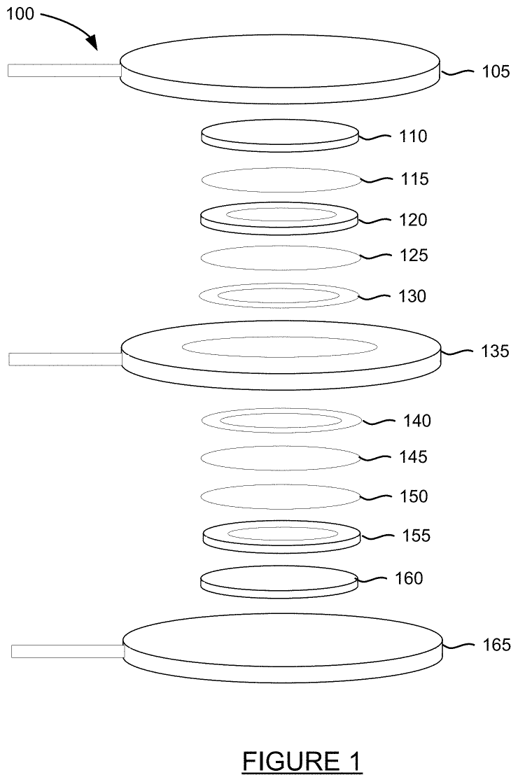

FIG. 1 illustrates a blown-up view of a three-electrode battery cell. The battery cell 100 of FIG. 1 includes upper body cover 105, metal plate 110, working electrode 115, PTFE 120, separator 125, and reference electrode 130. The reference body 135 is placed between the upper body cover and lower body cover. Below the reference body 135 are reference electrode 140, separator 145, working electrode 150, PTFE 155, and metal plate 160. Lower body cover 165 detectors to the reference body unit two encompass elements 140-160. In some instances, additional elements may be included in the three-electrode cell of FIG. 1, such as for example there is springs clamps and other items.

The three-electrode battery cell of FIG. 1 can be modeled after full battery cells having two electrodes, but can accurately provide for measurements of anode and cathode half-cell potentials. The anode and cathode potential measurements can be used to determine aspects of the cell, such as N/P ratio, capacity, and voltage window information.

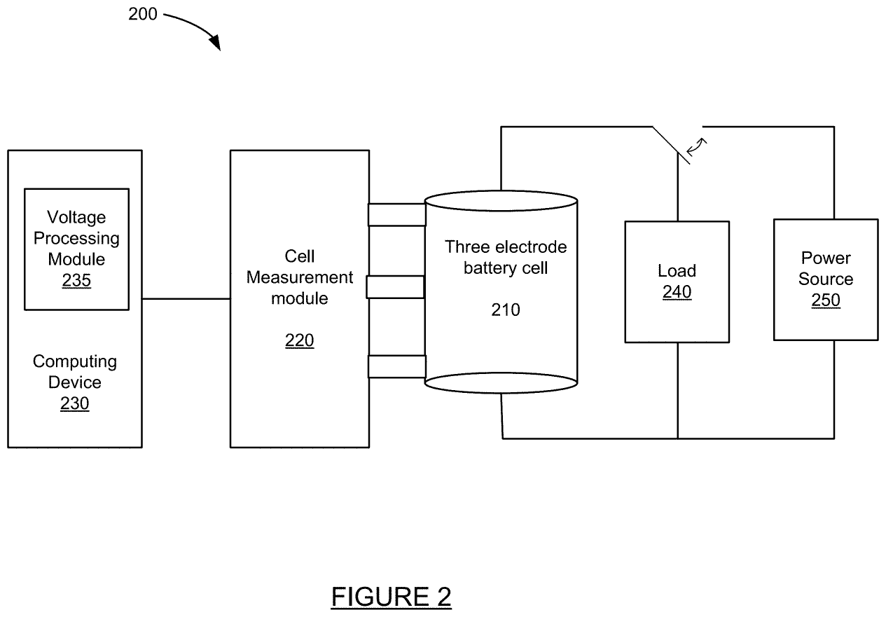

FIG. 2 is a block diagram of a system for computing information from measurements of a three-electrode battery cell. System 200 of FIG. 2 includes three-electrode battery cell 210, cell measurement 220, and computing device 230. Three-electrode battery cell 210 may include a three-electrode battery similar to that discussed with respect to FIG. 1. The battery may provide exact anode and cathode potential measurement data to cell measurement 220. For example, cell measurement 220 may collect anode half-cell voltages, cathode half-cell voltages, and other voltage or potential measurements and provide the measurement data to computing device 230.

Computing device 230 may communicate with cell measurement 220 and include voltage processing module 235. Voltage processing module 235 can receive the cell voltages and/or half-cell voltages to validate suitability of designed N/P ratio, voltage window determination for electrolyte stability, capacity prediction, the presence of lithium plating, and other information. In some instances, the cell measurement 220 and computing device 230 may be implemented on the same device or machine, and can for example be separate logical systems.

FIG. 2 also includes load 240 and power source 250. A switch or some other mechanism or circuitry can be used to couple the load or the power source to battery cell 210. Load 240 can be applied to battery cell 210 to discharge the battery cell. Power source 250 can be applied to battery cell 210 to charge the battery cell. The anode potential and cathode potential can each be measured during operation (i.e., during charge and discharge).

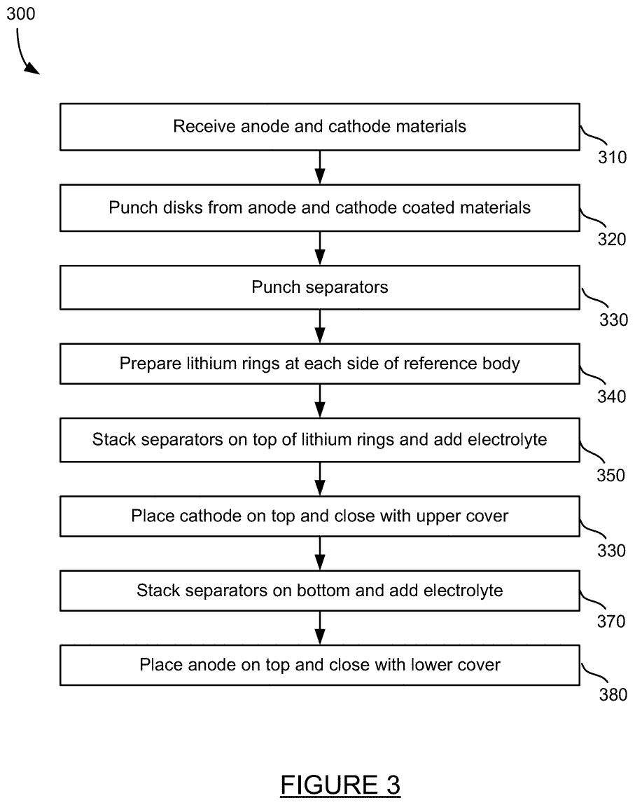

FIG. 3 is a method for manufacturing a three-electrode battery cell. The method of FIG. 3 may be performed all or in part by automated machinery. FIG. 3 begins with receiving an anode material and a cathode material at step 310. Discs are then punched or generated from the anode and cathode materials at step 320. The discs may be 16mm discs, or some other size disk. Separators may be punched at step 330. In some instances, the separators may be punched in 24 mm discs.

Lithium rings are prepared at each side of a reference body at step 340. Separators are stacked on top of lithium rings and then electrolyte is added to the battery assembly at step 350. A cathode is placed on top of the battery assembly and the assembly is closed with the upper cover at step 330. Separators are stacked on the bottom of the battery assembly and electrolyte is added to the battery assembly lower portion at step 370. Separators may be stacked on the bottom of the assembly and an electrolyte is added to the battery assembly at step 370. An anode is placed at the bottom of the battery assembly and the assembly is closed with the lower cover at step 380.

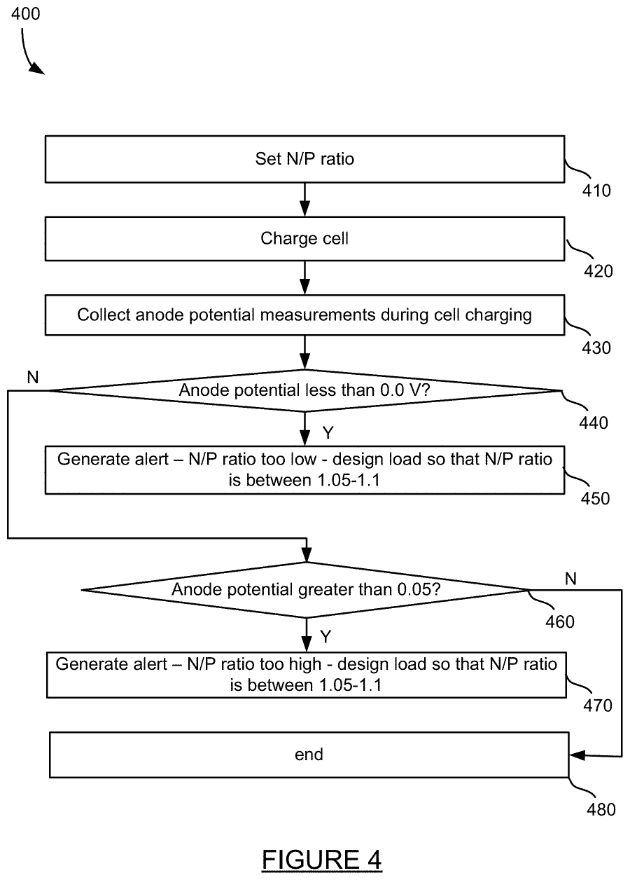

FIG. 4 is a method for tuning a negative-positive (N/P) ratio for a battery cell. An N/P ratio is set at step 410. The N/P ratio can be determined at the beginning of the electrode preparation. Battery cell charging begins at step 420 Anode potential is measured (vs. Li/Li+) during cell charging at step 430. If the anode has a potential of less than 0.0 V, it is an indication that lithium plating is occurring. If the anode potential is less than 0.0 V, an alert is generated, for example by computing device 230, at step 450. The alert can indicate that the N/P ratio is too low, and a load should be designed so that the N/P ratio is set between 1.05 and 1.1.

If the anode potential is not less than 0.0V at step 440, a determination is made as to whether the anode potential is greater than 0.05V at step 460. If an anode potential is greater than 0.05 V, the N/P ratio is too high, and the anode capacity isn't being fully utilized. If the anode potential is greater than 0.05V, an alert is generated that the N/P ratio is too high at step 470. The alert may indicate that a load should be designed so that the N/P ratio is between 1.05 and 1.1. If the anode potential is not greater than 0.05V at step 460, and the method of FIG. 4 ends at step 480

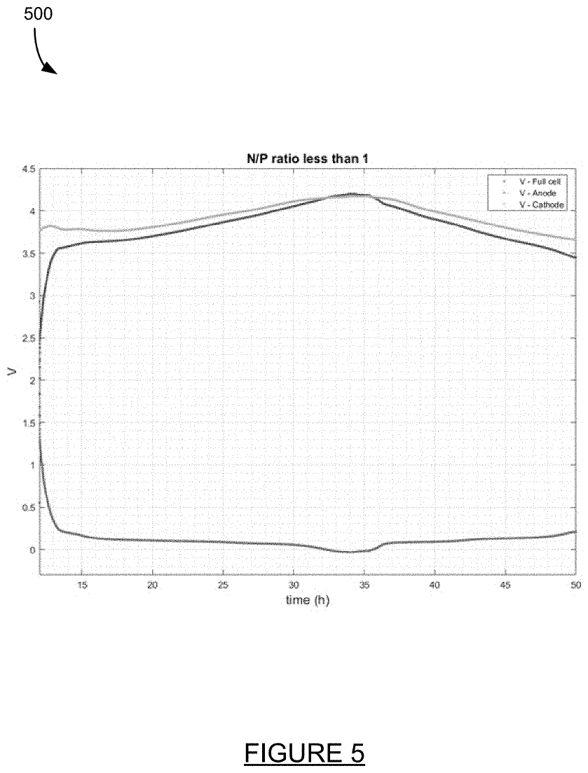

FIG. 5 illustrates a plot of an operational voltage window for a cell having an N/P ratio less than one. The plot of FIG. 5 includes a full cell plot, anode plot, and cathode plot. As shown, combining the anode and cathode plot values results in the full cell voltage plot. The anode voltage data at the bottom of the plot shows the data values below zero at a time between 33-34 hours, when the cell voltage approaches 4.2V (designed fully charged state), indicating that lithium plating is occurring. Because voltage window information indicates the anode voltage data is below 0.0V at this point, it is known that the N/P ratio is too low. The cathode potential, the upper most data in the plot, does not reach 4.2V, indicating that the designed capacity of the cathode cannot be fully utilized.

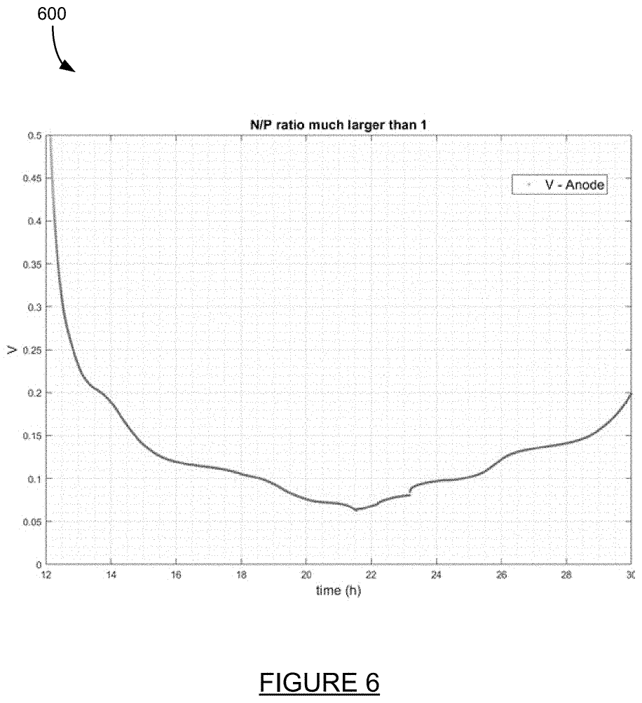

FIG. 6 illustrates an anode operational potential for cell within N/P ratio much larger than one. The lowest point of the anode voltage is approximately 0.06V. If an anode threshold was 0.05 V, this would mean that the N/P ratio is too large.

A battery cell having a large N/P ratio has anode capacity which is larger than a cathode capacity. The first cycle irreversible capacity loss increases with the increase of N/P ratio, and the anode capacity isn't and won't be fully utilized at its cut-off potential, at least in part because the capacity of graphite comes largely from the voltage between 0.075 to 0.05 V. With a higher capacity anode, anode materials are not utilized and the increasing irreversible capacity consumes more active Li in the cell and deteriorates the battery cell performance.

As shown in the abovementioned two examples, the anode potential and cathode potential can be monitored separately, N/P ratio tuning can be realized by analyzing the collected data, and optimal anode loading and cathode loading can be designed to optimize the battery cell itself.

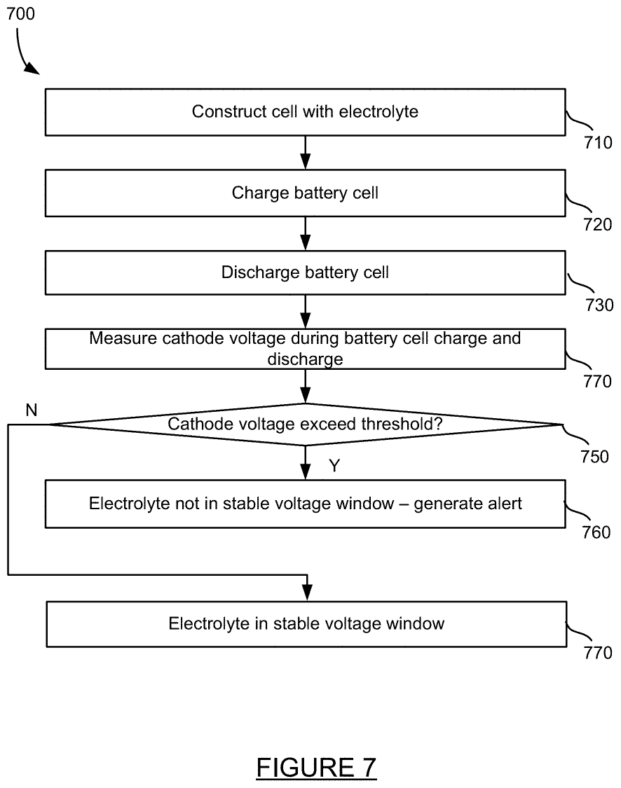

FIG. 7 is a method for determining electrolyte stability from a voltage window. A cell is constructed with an electrolyte at step 710. The construction may include steps discussed with respect to the method of FIG. 1. A battery cell may be charged at step 720. After charging, the battery cell may be discharged at step 730. A cathode voltage is measured during the battery cell charge and discharge at step 770. A determination is made as to whether the cathode voltage exceeds cathode voltage threshold at any time during the charge and discharge at step 750. In some instances, the cathode voltage threshold can be associated with an electrolyte and electrode system used in the battery cell. For example, the cathode voltage threshold can be 4.2 V, 4.3 V, 4.4 V, or some other value. If the cathode voltage exceeds the cathode voltage threshold, it is an indicator that electrolyte is getting oxidized and/or is decomposed, which causes reduced cell capacity and safety issues. In some instances, the 4.3 V voltage threshold is associated with a specification for the electrolyte and electrode system. In some instances, other values may be used as a voltage threshold depending on the electrolyte and electrode system. If the cathode voltage threshold is not exceeded, the electrolyte is determined to be within a stable voltage window. If the cathode voltage is exceeded, the electrolyte is determined to not be within a stable voltage window, and an alert is generated at step 760.

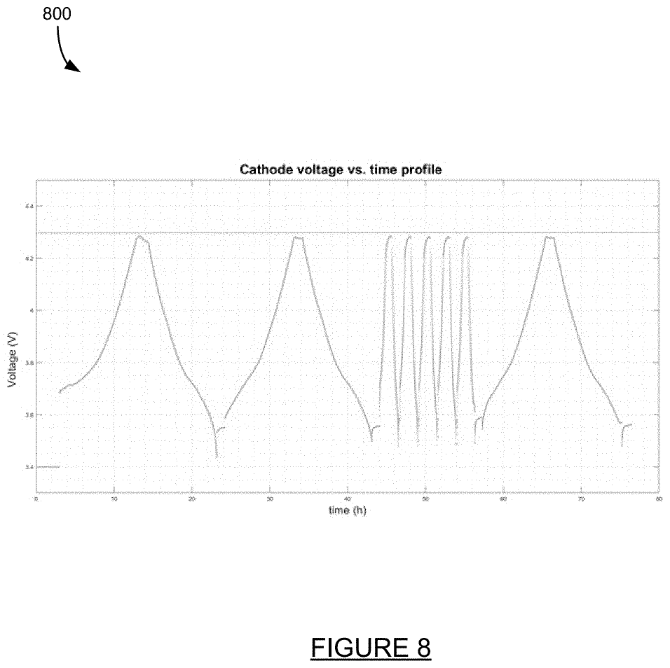

FIG. 8 illustrates a plot of a cathode potential over time. As shown, the cathode voltage is measured throughout various charge and discharge cycles. The battery cell is charged and discharged at different C-rates. Throughout each cycle, the cathode potential is always below 4.3V under all operating conditions. As shown by the plot of FIG. 8, it can be determined if the electrolyte stays within a stable voltage window (e.g., less than 4.3 V) when higher cell charging voltage or higher charging rate is applied during operation of the cell.

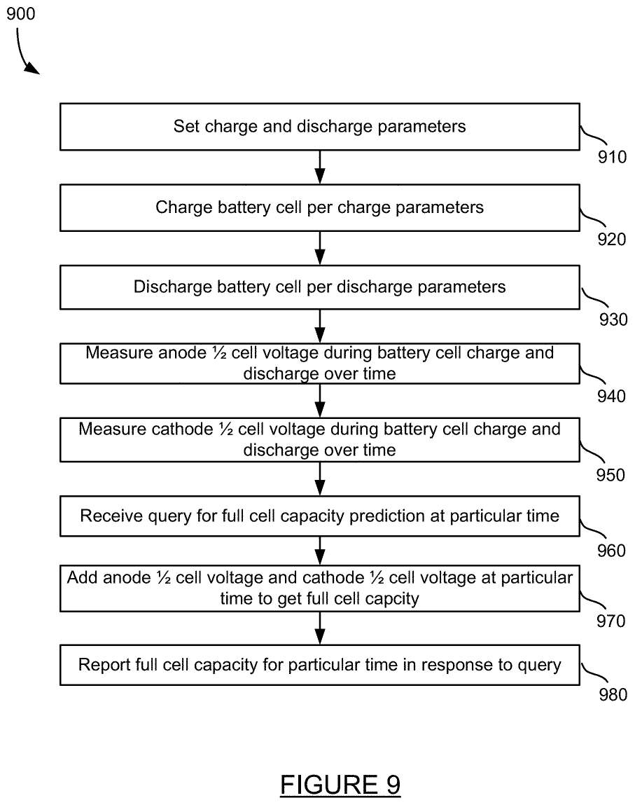

FIG. 9 illustrates a method for predicting capacity from half-cell potential measurements. Charge and discharge parameters are set at step 910. The charge and discharge parameters may specify a C-rate at which the battery cell is charged and/or discharged, for example via constant current and constant voltage (CCCV). The battery cell is charged per the charge parameters at step 920. Once the battery is charged, the battery cell is discharged per the discharge parameters at step 930.

An anode half-cell voltage is measured during the battery cell charge and discharge over time at step 940. Additionally, a cathode half-cell voltage is measured during the battery cell charge and discharge over time at step 950. The cathode half-cell voltages and anode half-cell voltages are stored along with the time data.

A query is received for a full cell capacity prediction at a particular time at step 960. An anode half-cell voltage and a cathode half-cell voltage associated with the particular time are added together at step 970. The addition of the half-cell voltage for the anode and the half-cell voltage cathode result in a full cell capacity. The full cell capacity for the particular time is reported in response to the query at step 980. By having access to the anode and cathode half-cell potential values over time, the full cell potential can be predicted for any point during the time window, or simulated for other times specified in the query.

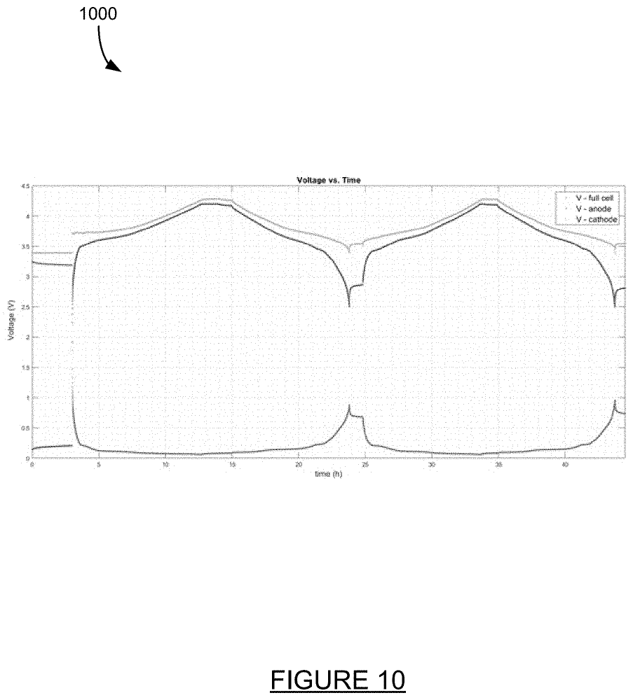

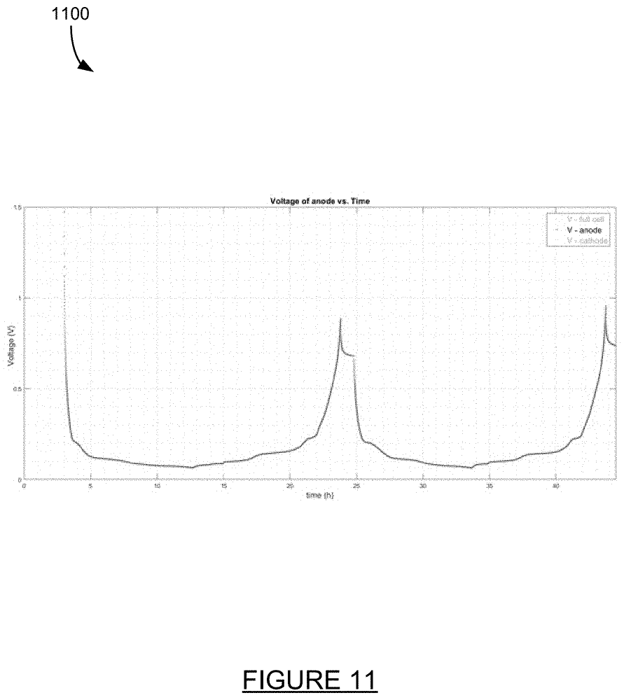

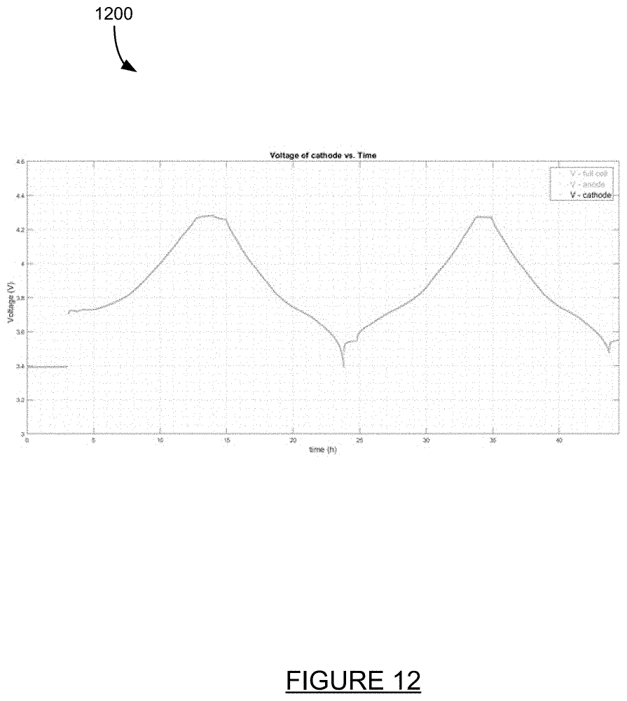

FIGS. 10-12 illustrates cathode and anode, potential data for predicting full cell capacity. FIG. 10 illustrates an overlap of three voltage profiles for a cathode potential, and a potential, and a cell voltage. The plot of FIG. 10 includes data for a full cell, an anode, and a cathode. The test condition is C/10 CCCV to 4.2V and CC to 2.5V for 2 cycles. When the cathode data points are subtracted from the anode data points, they result in values for the full cell data points. FIG. 11 illustrates a plot of an anode voltage versus time. In the anode voltage plot versus time, the anode voltage is a value of 0.066 V before CV stage, and 0.082 V at the end of the CV stage. After the first and a cycle, the voltage at 0.89 V. After the second voltage cycle, the voltage at 0.964V. FIG. 12 illustrates a plot of a cathode voltage versus time. The cathode voltage is 4.266 V before the CV stage, and 4.282 V at the end of the CV stage. At the end of the first cycle, potential is 3.39 V, and at the end of the second cycle the voltage is 3.46 V.

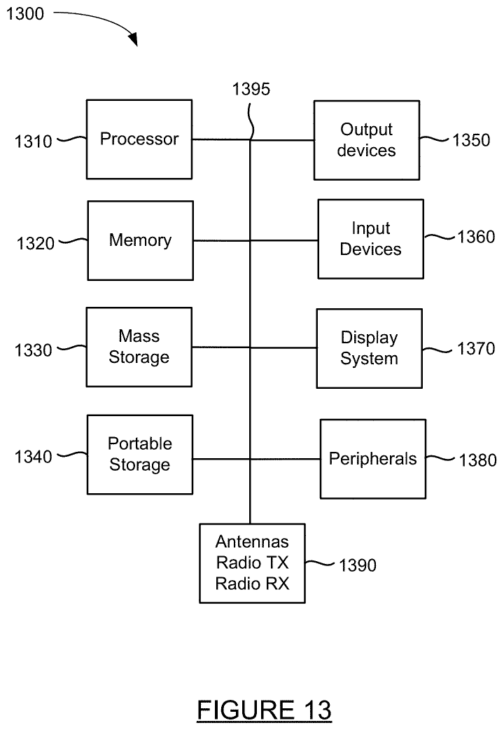

FIG. 13 is a block diagram of a computing environment for implementing the present technology. System 1300 of FIG. 13 may be implemented in the contexts a machine that implements cell measurement 220 and computing device 230. The computing system 1300 of FIG. 13 includes one or more processors 1310 and memory 1320. Main memory 1320 stores, in part, instructions and data for execution by processor 1310. Main memory 1320 can store the executable code when in operation. The system 1300 of FIG. 13 further includes a mass storage device 1330, portable storage medium drive(s) 1340, output devices 1350, user input devices 1360, a graphics display 1370, and peripheral devices 1380.

The components shown in FIG. 13 are depicted as being connected via a single bus 1390. However, the components may be connected through one or more data transport means. For example, processor unit 1310 and main memory 1320 may be connected via a local microprocessor bus, and the mass storage device 1330, peripheral device(s) 1380, portable storage device 1340, and display system 1370 may be connected via one or more input/output (I/O) buses.

Mass storage device 1330, which may be implemented with a magnetic disk drive, an optical disk drive, a flash drive, or other device, is a non-volatile storage device for storing data and instructions for use by processor unit 1310. Mass storage device 1330 can store the system software for implementing embodiments of the present technology for purposes of loading that software into main memory 1320.

Portable storage device 1340 operates in conjunction with a portable non-volatile storage medium, such as a flash drive, USB drive, memory card or stick, or other portable or removable memory, to input and output data and code to and from the computer system 1300 of FIG. 13. The system software for implementing embodiments of the present technology may be stored on such a portable medium and input to the computer system 1300 via the portable storage device 1340.

Input devices 1360 provide a portion of a user interface. Input devices 1360 may include an alpha-numeric keypad, such as a keyboard, for inputting alpha-numeric and other information, a pointing device such as a mouse, a trackball, stylus, cursor direction keys, microphone, touch-screen, accelerometer, wireless device connected via radio frequency, motion sensing device, and other input devices. Additionally, the system 1300 as shown in FIG. 13 includes output devices 1350. Examples of suitable output devices include speakers, printers, network interfaces, speakers, and monitors.

Display system 1370 may include a liquid crystal display (LCD) or other suitable display device. Display system 1370 receives textual and graphical information and processes the information for output to the display device. Display system 1370 may also receive input as a touch-screen.

Peripherals 1380 may include any type of computer support device to add additional functionality to the computer system. For example, peripheral device(s) 1380 may include a modem or a router, printer, and other device.

The system of 1300 may also include, in some implementations, antennas, radio transmitters and radio receivers 1390. The antennas and radios may be implemented in devices such as smart phones, tablets, and other devices that may communicate wirelessly. The one or more antennas may operate at one or more radio frequencies suitable to send and receive data over cellular networks, Wi-Fi networks, commercial device networks such as a Bluetooth device, and other radio frequency networks. The devices may include one or more radio transmitters and receivers for processing signals sent and received using the antennas.

The components contained in the computer system 1300 of FIG. 13 are those typically found in computer systems that may be suitable for use with embodiments of the present invention and are intended to represent a broad category of such computer components that are well known in the art. Thus, the computer system 1300 of FIG. 13 can be a personal computer, handheld computing device, smart phone, mobile computing device, workstation, server, minicomputer, mainframe computer, or any other computing device. The computer can also include different bus configurations, networked platforms, multi-processor platforms, etc. Various operating systems can be used including Unix, Linux, Windows, Macintosh OS, Android, as well as languages including Java, .NET, C, C++, Node.JS, and other suitable languages.

The foregoing detailed description of the technology herein has been presented for purposes of illustration and description. It is not intended to be exhaustive or to limit the technology to the precise form disclosed. Many modifications and variations are possible in light of the above teaching. The described embodiments were chosen to best explain the principles of the technology and its practical application to thereby enable others skilled in the art to best utilize the technology in various embodiments and with various modifications as are suited to the particular use contemplated. It is intended that the scope of the technology be defined by the claims appended hereto.

1. A system for analyzing a battery cell design using a three-electrode battery cell, comprising:
one or more processors;
memory; and
one or more modules stored in memory and executed by one or more processors to:
measure an anode potential of a three-electrode battery cell during charging and discharging of the three-electrode battery cell, the three-electrode battery cell including an anode, a cathode, and a reference electrode, the reference electrode displaced between the anode and the cathode and enabling a half cell potential to be measured for the anode and a half cell potential to be measured for the cathode;
measure the cathode potential during charging and discharging, and
optimize design of the three-electrode battery cell based on the measured anode potential measurement and cathode potential measurement.

2. The system of claim 1, wherein optimizing includes:
determining whether an anode potential is within a desired range; and
adjusting a positive/negative ratio based the anode potential.

3. The system of claim 2, wherein optimizing includes comparing the anode potential to a threshold.

4. The system of claim 3, wherein the threshold is a minimum value, a value for the anode potential below the threshold indicating the presence of lithium plating.

5. The system of claim 2, wherein the threshold is a maximum value, a value for the anode potential over the threshold indicating the anode failure to utilize its full capacity.

6. The system of claim 1, further comprising:
discharging the anode and the cathode;
measuring the anode potential during discharge over time;
measuring the cathode potential during discharge over time; and
predicting full cell capacity for a particular time based on the anode potential and cathode potential at a particular time during the charge and discharge.

7. The system of claim 6, wherein predicting includes adding the anode half-cell potential and the cathode half-cell potential at the particular time.

8. The system of claim 7, further comprising receive a query for the full cell potential at the particular time, the full cell capacity prediction performed in response to receiving the query; and
responding to the query with the predicted full cell capacity.

9. A system for analyzing a battery cell design using a three-electrode battery cell, comprising:
one or more processors;
memory; and
one or more modules stored in memory and executed by one or more processors to:
charge and discharge a cathode of a three-electrode battery cell, the three-electrode battery cell including an anode, the cathode, and a reference electrode, the reference electrode displaced between the anode and the cathode and enabling a half cell potential to be measured for the anode and a half cell potential to be measured for the cathode;
measure the cathode potential during charging;
measure the cathode potential during discharging; and
optimize design of the three-electrode battery cell based on the maximum cathode voltage during the charging and discharging.

10. The system of claim 9, wherein optimizing includes:
comparing the maximum cathode potential to a threshold; and
generating an alert regarding the stability of an electrolyte within the three-electrode battery cell if the maximum cathode potential is greater than a threshold.

11. The system of claim 10, wherein the threshold is 4.3 volts.

12. The system of claim 9, further comprising:
charging and discharging the anode; and
measuring the anode potential during charging and discharging,
wherein optimizing includes reporting a full cell capacity predicted for a particular time based on the anode potential and cathode potential at the particular time

13. The system of claim 12, wherein optimizing includes determining the full cell capacity by adding the corresponding anode potential and cathode potential at the particular time.
